(19) United States
(12) Patent Application Publication
(10) Pub. No.: US 2025/0047069 A1
(43) Pub. Date: Feb. 6, 2025

(54) Semiconductor Laser

(71) Applicant: Nippon Telegraph and Telephone Corporation, Tokyo (JP)

(72) Inventors: Takuro Fujii, Musashino-shi, Tokyo (JP); Koji Takeda, Musashino-shi, Tokyo (JP); Toru Segawa, Musashino-shi, Tokyo (JP); Yoshiho Maeda, Musashino-shi, Tokyo (JP); Shinji Matsuo, Musashino-shi, Tokyo (JP)

(21) Appl. No.: 18/721,848

(22) PCT Filed: Dec. 20, 2021
(86) PCT No.: PCT/JP2021/047032

§ 371 Date: Jun. 19, 2024

(51) Int. Cl. H01S 5/12; H01S 5/06

(52) U.S. Cl. CPC H01S 5/1221; H01S 5/0612; H01S 5/1234

(57) ABSTRACT

A semiconductor laser includes: a waveguide structure including, in order, a first semiconductor layer, an active layer, and a second semiconductor layer; a p-type semiconductor layer disposed in contact with one side surface of the active layer; an n-type semiconductor layer disposed in contact with the other side surface of the active layer; a waveguide layer optically coupled to the active layer in a waveguide direction; a first diffraction grating disposed on either one of a lower surface of the first semiconductor layer, an upper surface of the second semiconductor layer, and a side surface of the active layer; a second diffraction grating disposed on either one of a lower surface and an upper surface of the waveguide layer; and a refractive index control unit for changing a refractive index of the waveguide layer. The semiconductor laser can achieve a good high-temperature operation with a simple configuration.

### TECHNICAL FIELD

The present invention relates to a semiconductor laser having a diffraction grating and capable of operating at high temperatures.

### BACKGROUND ART

In recent years, in order to cope with the rapidly increasing transmission capacity of the Internet, it has become necessary to reduce the power consumption of optical devices, and in particular, semiconductor lasers capable of operating over a wide temperature range, from room temperature to high temperature, are needed.

In addition, as the module mounting density of optoelectronic devices increases, the device temperature increases, requiring semiconductor lasers capable of operating at high temperatures.

Conventionally, a semiconductor such as a DFB laser (Distributed feedback laser diode) can oscillate in a single mode by a structure comprising an active layer having a quantum well structure and a resonator structure such as a diffraction grating (NPLs 1 and 2). In order to obtain good laser characteristics, it is necessary that the gain wavelength of the active layer coincides with the resonance wavelength.

### CITATION LIST

### Non Patent Literature

[NPL 1] T. Fujii et al., “Heterogeneously Integrated Membrane Lasers on Si Substrate for Low Operating Energy Optical Links,” in IEEE Journal of Selected Topics in Quantum Electronics, vol. 24, No. 1, pp. 1-8, January-February 2018, Art No. 1500408, doi: 10.1109/JSTQE.2017.2778510.
[NPL 2] “Widely tunable laser with lattice filter on Si photonic platform,” Takuma Aihara, Tatsurou Hiraki, Takuro Fujii, Koji Takeda, Tai Tsuchizawa, Takaaki Kakitsuka, Hiroshi Fukuda, Shinji Matsuo, Compound Semiconductor Week 2021 (CSW 2021) TuA2-5 May 2021
[NPL 3] M. Chacinski, M. Isaksson and R. Schatz, “High-speed direct Modulation of widely tunable MG-Y laser,” in IEEE Photonics Technology Letters, vol. 17, No. 6, pp. 1157-1159-6-2005, doi: 10.1109/LPT.2005.846489.
[NPL 4] S. Paul et al., “10-Gb/s Direct Modulation of Widely Tunable 1550-nm MEMS VCSEL,” in IEEE Journal of Selected Topics in Quantum Electronics, vol. 21, No. 6, pp. 436-443, November-December 2015, Art No. 1700908, doi: 10.1109/JSTQE.2015.2418218.
[NPL 5] K. Hasebe, T. Sato, K. Takeda, T. Fujii, T. Kakitsuka and S. Matsuo, “High-Speed Modulation of Lateral p-i-n Diode Structure Electro-Absorption Modulator Integrated With DFB Laser,” in Journal of Lightwave Technology, vol. 33, No. 6, pp. 1235-1240, 15 Mar. 15, 2015, doi: 10.1109/JLT.2014.2383385.
[NPL 6] Gladyshev, A. G., Novikov, I. I., Karachinsky, L. Y. et al., “Optical properties of InGaAs/InGaAlAs quantum wells for the 1520-1580 nm spectral range,” Semiconductors 50, 1186-1190 (2016). https://doi.org/10.1134/S1063782616090098.

### SUMMARY OF INVENTION

### Technical Problem

In conventional DFB lasers, the temperature dependence of the gain wavelength and the temperature dependence of the refractive index are different, so changing the operating temperature causes a mismatch between the material gain and the oscillation wavelength, which degrades the characteristics.

Therefore, in the conventional DFB lasers, in order to operate with good characteristics at high temperatures, a configuration that operates at low temperatures with a temperature controller, configuration that integrates a semiconductor modulator and a semiconductor optical amplifier, a configuration that uses materials that excel in high temperature operation for the active layer, and the like have been disclosed (NPLs 3 to 6).

However, since these configurations are complicated, there are problems such as complication of the manufacturing process and increase of the manufacturing cost.

### Solution to Problem

In order to solve the above problems, a semiconductor laser according to the present invention includes: a waveguide structure including, in order, a first semiconductor layer, an active layer, and a second semiconductor layer; a p-type semiconductor layer disposed in contact with one side surface of the active layer; an n-type semiconductor layer disposed in contact with the other side surface of the active layer; a waveguide layer optically coupled to the active layer in a waveguide direction; a first diffraction grating disposed on either one of a lower surface of the first semiconductor layer, an upper surface of the second semiconductor layer, and a side surface of the active layer; a second diffraction grating disposed on either one of a lower surface and an upper surface of the waveguide layer; and a refractive index control unit for changing a refractive index of the waveguide layer.

### Advantageous Effects of Invention

According to the present invention, a semiconductor laser capable of achieving a good high-temperature operation with a simple configuration can be provided.

### BRIEF DESCRIPTION OF DRAWINGS

FIG. 1A is a top perspective view showing a configuration of a semiconductor laser according to a first embodiment of the present invention.

FIG. 1B is a cross-sectional view taken along IB-IB′, showing the configuration of the semiconductor laser according to the first embodiment of the present invention.

FIG. 1C is a cross-sectional view taken along IC-IC′, showing the configuration of the semiconductor laser according to the first embodiment of the present invention.

FIG. 2A is a diagram for explaining an operation of the semiconductor laser according to the first embodiment of the present invention.

FIG. 2B is a diagram for explaining an operation of the semiconductor laser according to the first embodiment of the present invention.

FIG. 3 is a top perspective view showing an example of the configuration of the semiconductor laser according to the first embodiment of the present invention.

FIG. 4 is a top perspective view showing a configuration of a semiconductor laser according to a second embodiment of the present invention.

FIG. 5 is a diagram for explaining an operation of the semiconductor laser according to the second embodiment of the present invention.

FIG. 6A is a diagram for explaining an operation of the semiconductor laser according to the second embodiment of the present invention.

FIG. 6B is a diagram for explaining an operation of the semiconductor laser according to the second embodiment of the present invention.

FIG. 7A is a diagram for explaining an operation of the semiconductor laser according to the second embodiment of the present invention.

FIG. 7B is a diagram for explaining an operation of the semiconductor laser according to the second embodiment of the present invention.

FIG. 8A is a diagram for explaining an operation of the semiconductor laser according to the second embodiment of the present invention.

FIG. 8B is a diagram for explaining an operation of the semiconductor laser according to the second embodiment of the present invention.

### DESCRIPTION OF EMBODIMENTS

### First Embodiment

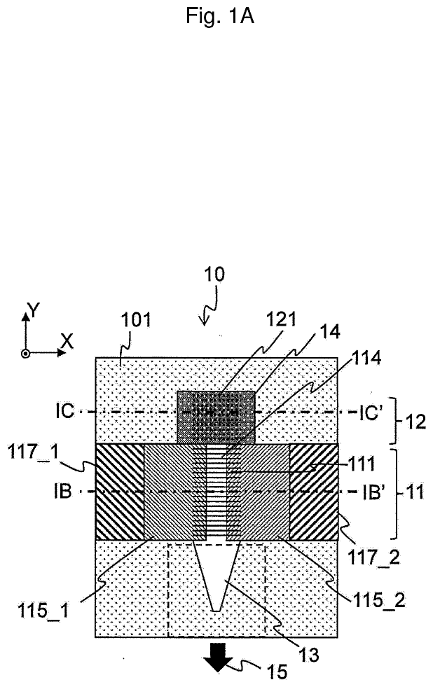

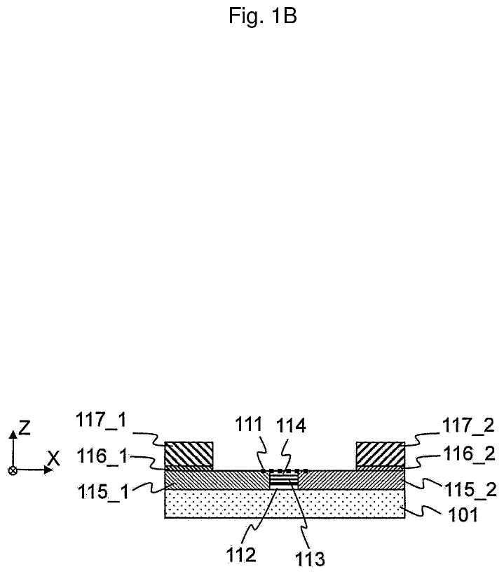

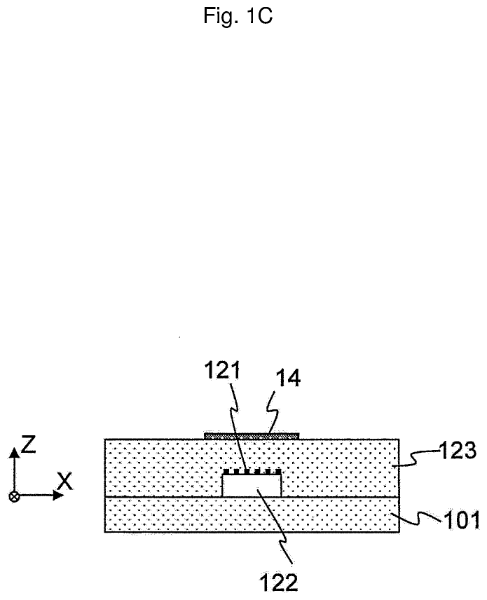

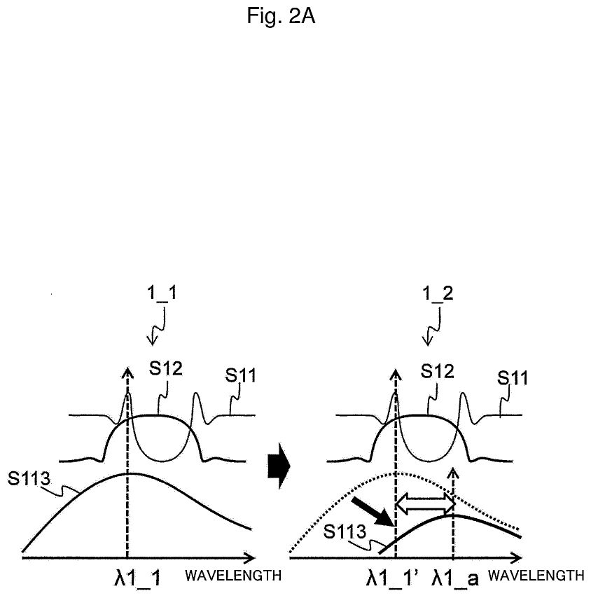

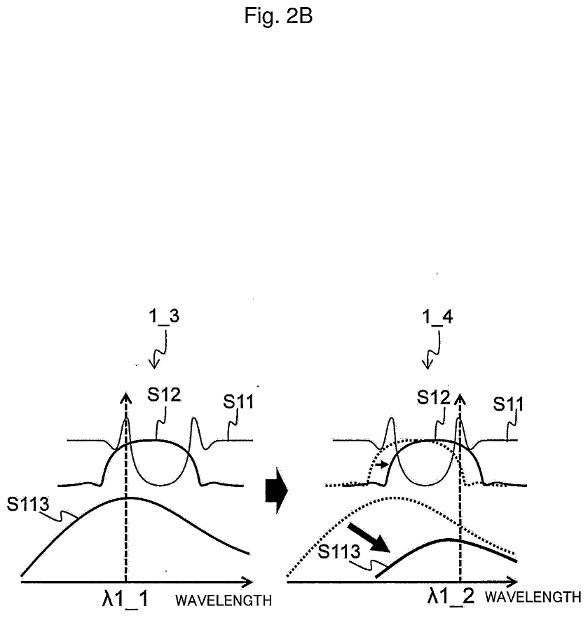

A semiconductor laser according to a first embodiment of the present invention will be described hereinafter with reference to FIGS. 1A to 2B.

### <Configuration of Semiconductor Laser>

As shown in FIG. 1A, a semiconductor laser 10 according to the present embodiment includes a DFB (Distributed feedback) region 11, a DBR (Distributed Bragg Reflector) region 12, and an output waveguide 13, on a SiO₂ 101.

Here, as the SiO₂ 101, a dielectric such as SiN or SiNO other than SiO₂ may be used. The SiO₂ 101 is formed on a substrate. Si is used for the substrate, and a semiconductor or a dielectric other than Si may be used.

As shown in FIG. 1B, the DFB region 11 is formed into a waveguide structure by stacking a first semiconductor layer (InP) 112, a multi quantum well (MQW) 113 serving as an active layer, and a second semiconductor layer (InP) 114 on the SiO₂ 101. A p-type InP layer 115_1 is arranged in contact with one side surface of this waveguide structure in a width direction (X direction in the diagram), and a p-type electrode (for example, gold) 117_1 is provided on the p-type InP layer 115_1 via a p-type contact layer (for example, InGaAs) 116_1. An n-type InP layer 115_2 is arranged in contact with the other side surface, and an n-type electrode (for example, gold) 117_2 is provided on the n-type InP layer 115_2 via an n-type contact layer (for example, n-type InGaAs) 116_2.

Here, for example, the MOW active layer 113 is composed of an InGaAsP well layer and an InGaAsP barrier layer of a 1.55-μm wavelength band, and has a thickness of approximately 105 nm in six cycles. The thicknesses of the first semiconductor layer (InP) 112 and the second semiconductor layer (InP) 114 are 165 nm and 80 nm, respectively. The thickness of SiO₂ 101 is 2 μm, and the thicknesses of the p-type InP layer 115_1 and the n-type InP layer 115_2 are 350 nm.

Here, the MOW active layer 113 may be in a 1.31-μm wavelength band. InGaAs, InGaAlAs, GaInNAs, or the like may be used for the MOW instead of InGaAsP. Configurations such as the cycle and thickness of the MOW may employ other configurations.

In the DFB region 11, a DFB diffraction grating (first diffraction grating) 111 is provided on an upper surface of the second semiconductor layer (InP) 114 above the active layer 113. The coupling coefficient of the DFB (first diffraction grating diffraction grating) 111 is determined by the refractive index of InP and the refractive index of air. Here, in the DFB diffraction grating 111, for example, a pitch (cycle) is approximately 200 nm to 300 nm, and a depth is approximately 10 nm to 50 nm, which are set by a desired light emission (oscillation) wavelength and a coupling coefficient.

Further, a diffraction grating may be provided at the boundary between the first semiconductor layer (InP) 112 and the SiO₂ 101 under the active layer 113. In this case, the coupling coefficient of the diffraction grating is determined by the refractive index of InP and the refractive index of SiO₂.

Further, a diffraction grating may be provided on a side surface of the active layer 113, that is, a boundary between the active layer 113 and the p-type InP layer 115_1 or a boundary between the active layer 113 and the n-type InP layer 115_2. In this case, a mask having a diffraction grating shape (concave-convex shape) pattern may be used in the step of processing the active layer 113 into a waveguide structure.

Thus, the DFB region 11 of the semiconductor laser 10 has the configuration of a membrane-type laser, in which current is injected laterally into the active layer 113, the laser oscillates, and laser beam is emitted (arrow 15 in the diagram).

As shown in FIG. 1A, the DBR region 12 is connected to the DFB region 11 in a waveguide direction (Y direction in the figure). Here, the DBR region 12 may be optically coupled to the DFB region 11.

The DBR region 12 includes, as shown in FIG. 1C, an InP waveguide layer 122 and an SiO₂ cladding 123 covering the InP waveguide layer 122, on the SiO₂ 101, and includes a heater 14 on a surface of the SiO₂ cladding 123.

In the DBR region 12, a DBR diffraction grating (second diffraction grating) 121 is provided at a boundary between an upper surface of the InP waveguide layer 122 and the SiO₂ cladding 123. Alternatively, the DBR diffraction grating 121 may be provided at a boundary between a lower surface of the InP waveguide layer 122 and the SiO₂ 101.

Here, in the DBR diffraction grating 121, for example, a pitch (cycle) is approximately 200 nm to 300 nm, and a depth is approximately 10 nm to 50 nm, which are set by a desired light emission (oscillation) wavelength and a coupling coefficient. In particular, the pitch (cycle) is set in relation to the emission wavelength of the DFB diffraction grating (first diffraction grating) 111, as will be described later.

In the DBR region 12, the temperature of the InP waveguide layer 122 is changed by the heater 14, to change the refractive index. As a result, the coupling coefficient of the diffraction grating 121 of the InP waveguide layer 122 is changed, and the peak wavelength is changed.

The heater 14 may be made of metal or resin. Although an example of arranging the heater 14 on the surface of the SiO₂ cladding 123 has been described, the present invention is not limited thereto; the heater 14 may be embedded in the SiO₂ cladding 123 or the SiO₂ 101, and the temperature of the InP waveguide layer 122 may be changed.

Here, for example, the lengths of the DFB region 11 and the DBR region 12 are 75 μm and 50 μm, respectively, and the width of the active layer 113 of the DFB region 11 and the width of the InP waveguide 122 of the DBR region 12 are 1.0 μm.

The output waveguide 13 has a tapered shape that narrows in width toward an output end. Here, the output waveguide 13 does not have to be arranged.

### <Operation of Semiconductor Laser>

Operations of the semiconductor laser 10 according to the present embodiment will be described below.

In the conventional DFB laser, since the DFB diffraction grating having no λ/4 shift has two stopband edge emission wavelengths (short wavelength side and long wavelength side), oscillation can be performed at two stopband edge wavelengths matching the wavelength of the gain peak of the MOW active layer 113.

FIGS. 2A and B show an emission spectrum S11 of the DFB diffraction grating, a reflection spectrum S12 of the DBR diffraction grating, and a gain spectrum S113 of the MQW active layer, in the semiconductor laser (Distributed Reflector laser, DR laser) in which the DBR diffraction grating is integrated in the DFB laser.

FIG. 2A shows each spectrum (1_1) at room temperature and each spectrum (1_2) at high temperature in a conventional DR laser.

In the conventional DR laser, the DBR diffraction grating selects and oscillates a stopband emission wavelength (for example, λ1_1) of either one of the short wavelength side and the long wavelength side of the DFB diffraction grating (1_1 in the diagram).

At high temperature, the gain peak S113 of the MQW active layer shifts to the long wavelength side (wavelength λ1_a), and the intensity decreases. On the other hand, although the oscillation wavelength by the DFB diffraction grating and the DBR diffraction grating is also shifted to the long wavelength side, the shift amount of this wavelength (λ1_1′) is smaller than the shift amount of the gain peak. As a result, a deviation occurs between the gain peak (λ1_a) of the MOW active layer and the peak (λ1_1′) of the oscillation wavelength (1_2 in the diagram). Thus, the characteristics of the DR laser at a high temperature are deteriorated.

FIG. 2B shows each spectrum (1_3) at room temperature and each spectrum (1_4) at high temperature in the semiconductor laser 10 according to the present embodiment.

In the semiconductor laser 10, at room temperature, when the heater 14 is off, an oscillation wavelength by the DFB diffraction grating (first diffraction grating) 111 and the DBR diffraction grating (second diffraction grating) 121 and a wavelength of a gain peak of the MOW active layer 113 match at wavelength λ1_1 (1_3 in the diagram). Here, the Bragg wavelength of the DBR diffraction grating 121 is set so as to oscillate at the emission wavelength on the short wavelength side of the DFB diffraction grating 111.

At high temperature, the heater 14 arranged in the vicinity of the InP waveguide layer 122 having the DBR diffraction grating 121 is turned on to raise the temperature (for example, approximately 100° C.), and the temperature of the InP waveguide layer 122 of the DBR diffraction grating 121 is increased. As a result, the refractive index of the InP waveguide layer 122 of the DBR diffraction grating 121 is increased, and the Bragg wavelength of the DBR diffraction grating 121 is shifted to the long wavelength side.

As a result, in the semiconductor laser 10, the Bragg wavelength of the DBR diffraction grating 121 matches the emission wavelength on the long wavelength side of the DFB diffraction grating 111, and oscillates at the emission wavelength (λ1_2) on the long wavelength side.

At high temperature, the gain peak of the MQW active layer 113 is also shifted to the long wavelength side as described above (1_4 in the diagram).

In this manner, in the semiconductor laser 10, at high temperature, since the emission wavelength on the long wavelength side of the DFB diffraction grating 111 that matches the Bragg wavelength of the DBR diffraction grating 121 oscillates in unison with the gain peak of the MOW active layer 113, the reduction of the output at high temperature is suppressed, and good high-temperature operation characteristics are obtained.

According to the semiconductor laser according to the present embodiment, a decrease in output at high temperature is suppressed, and good high-temperature operation characteristics can be obtained.

### Modifications

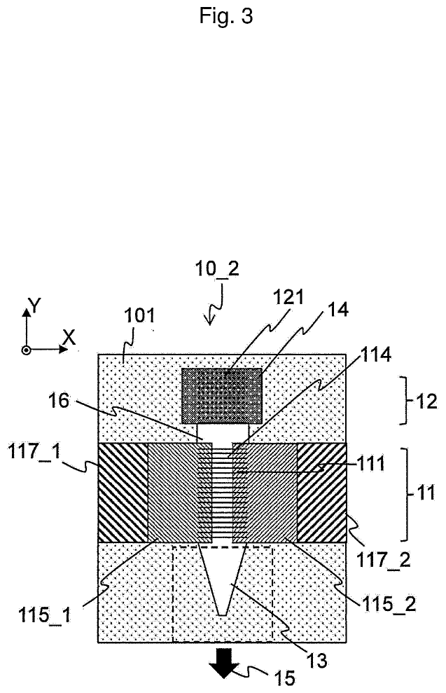

As shown in FIG. 3, a semiconductor laser 10_2 according to a modification of the present embodiment includes a waveguide region 16 between the DFB region 11 and the DBR region 12.

The waveguide region 16 has, on the SiO₂ 101, the InP waveguide layer 122 and the SiO₂ cladding 123 covering the InP waveguide, and has the same layer configuration as the DBR region 12, but a diffraction grating and the heater 14 are not provided. The length of the waveguide region 16 is approximately 20 μm.

In other words, the InP waveguide layer 122 of the DBR region 12 includes the DBR diffraction grating (second diffraction grating) 121 and the heater 14, with a predetermined distance (for example, 20 v) from the active layer 113 of the DFB region 11.

The waveguide region 16 suppresses heat conduction from the DBR region 12 to the DFB region 11 when the temperature is raised by the heater 14.

In the configuration with no waveguide region 16, heat is conducted from the DBR region 12 to the DFB region 11 when the temperature is raised by the heater 14, thereby increasing the temperature of the DFB region 11. Thus, the peak wavelength of the DFB diffraction grating (first diffraction grating) 111 is shifted to the long wavelength side, and the gain peak of the MOW active layer 113 is shifted to the long wavelength side, reducing the intensity.

As a result, since the shift amount of the peak wavelength of the DBR diffraction grating 121 required for matching the emission wavelength of the DFB diffraction grating 111 with the emission wavelength on the long wavelength side increases, the power consumption of the heater increases.

Furthermore, since the intensity of the gain peak of the MQW active layer 113 decreases, the output of the semiconductor laser decreases.

On the other hand, in the semiconductor laser 10_2 according to the present modification, since heat conduction from the DBR region 12 to the DFB region 11 is suppressed, the temperature increase in the DFB region 11 is suppressed, and the shift of the peak wavelength of the DFB diffraction grating 111, the shift of the gain peak wavelength of the MOW active layer 113, and the reduction of the intensity are suppressed. As a result, the increase in power consumption of the heater and the decrease in output of the semiconductor laser are suppressed.

According to the semiconductor laser according to the present modification, the impact of the temperature rise of the heater at high temperature on the DFB region 11 can be suppressed, and good high-temperature operation characteristics can be realized.

Although the present modification has shown an example in which the waveguide region without a diffraction grating and a heater is provided, the present invention is not limited thereto. A configuration is possible in which a waveguide region (InP) not provided with a diffraction grating and a heater has a tapered shape which becomes thinner from the DFB region toward the DBR region, an Si waveguide optically coupled to the waveguide region (InP) is provided in the SiO₂ 101 below the waveguide region (InP), and the Si waveguide includes a diffraction grating and a heater.

### Second Embodiment

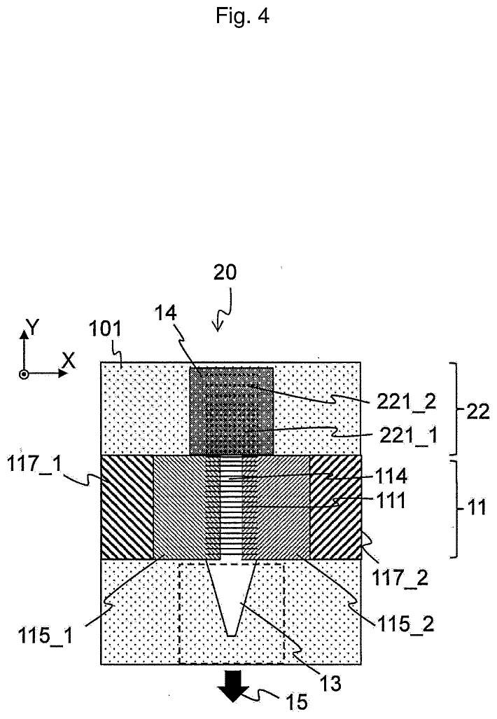

A semiconductor laser according to a second embodiment of the present invention will be described hereinafter with reference to FIGS. 4 to 8B.

### <Configuration of Semiconductor Laser>

As shown in FIG. 4, a semiconductor laser 20 according to the present embodiment includes a DFB region 11 and a DBR region 22 on a SiO₂ 101.

The DBR region 22 has one DBR diffraction grating (second diffraction grating) 221_1 and another DBR diffraction grating (third diffraction grating) 221_2 optically coupled to the DBR diffraction grating (second diffraction grating) 221_1 in a waveguide direction (Y direction in the diagram). The other configurations are the same as those of the first embodiment.

Here, in the waveguide direction, a first diffraction grating 111, the DBR diffraction grating (second diffraction grating) 221_1, and the other DBR diffraction grating (third diffraction grating) 221_2 are arranged in order. In addition, in the waveguide direction, the first diffraction grating 111, the DBR diffraction grating (third diffraction grating) 221_2, and the DBR diffraction grating (second diffraction grating) 221_1 may be arranged in order.

Furthermore, the first diffraction grating 111, the DBR diffraction grating (second diffraction grating) 221_1, and the DBR diffraction grating (third diffraction grating) 221_2 may be arranged in contact with each other or at intervals, or may be optically coupled to each other.

The lengths of the first diffraction grating 111, the second diffraction grating 221_1, and the third diffraction grating 221_2 are, for example, 75 μm, 50 μm, and 50 μm, respectively.

A heater 14 is positioned on a surface of the SiO₂ cladding 123 at a location that can raise the temperature of the InP waveguide layer 122 in the vicinity of the second diffraction grating 221_1 and the third diffraction grating 221_2. Here, an example in which the heater 14 is arranged on the surface of the SiO₂ cladding 123 has been described, but the present invention is not limited thereto; the heater 14 may be embedded in the SiO₂ cladding 123 to change the temperature of the InP waveguide layer 122.

In the DBR region 22, the pitch (cycle) of each diffraction grating is set so that the Bragg wavelength of the third diffraction grating 221_2 is on the longer wavelength side than the Bragg wavelength of the second diffraction grating 221_1.

Further, the Bragg wavelength of the second diffraction grating 221_1 is set to the shorter wavelength side than the emission wavelength of the short wavelength side of the DFB diffraction grating (first diffraction grating) 111, in a state where the heater 14 is off. Here, the Bragg wavelength of the second diffraction grating 221_1 may be set to a degree that matches the emission wavelength of the short wavelength side of the DFB diffraction grating 111 when the heater 14 is on, as described below.

As a result, the semiconductor laser 20 oscillates at the emission wavelength on the short wavelength side of the DFB diffraction grating 111 at room temperature when the heater 14 is on. Here, the emission wavelength is approximately the same as the MQW gain peak wavelength.

### <Operation of Semiconductor Laser>

In the operation of the semiconductor laser 20 according to the present embodiment, the heater 14 is turned on at room temperature and turned off at high temperature, which is different from the first embodiment, and details will be described below.

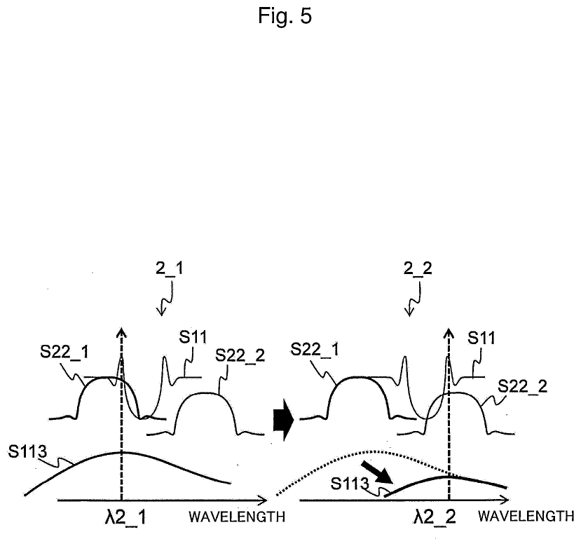

FIG. 5 shows a reflection spectrum S11 of the DFB diffraction grating (first diffraction grating) 111, a reflection spectrum S22_1 of one DBR diffraction grating (second diffraction grating) 221_1, a reflection spectrum S22_2 of another DBR diffraction grating (third diffraction grating) 221_2, and a gain spectrum S113 of the MQW active layer 113 in the semiconductor laser 20. In the diagram, each spectrum (2_1) at room temperature and each spectrum (2_2) at high temperature are shown.

At room temperature, when the heater 14 is on, the Bragg wavelength of the second diffraction grating 221_1 matches the emission wavelength of the DFB diffraction grating 111 on the short wavelength side (wavelength λ2_1), and oscillation is performed (2_1 in the diagram).

At high temperature, as in the first embodiment, since the gain peak S113 of the MOW active layer shifts to the long waveguide side more than the oscillation wavelength S11 by the DFB diffraction grating and the DBR diffraction grating, the characteristics of the DR laser at high temperature become deteriorated.

At this time, by turning off the heater 14, the emission wavelength on the long wavelength side of the DFB diffraction grating 111 matches the Bragg wavelength of the third diffraction grating 221_2, and oscillates at a wavelength λ2_2 which is approximately equal to the wavelength of the gain peak of the MQW active layer 113 (2_2 in the diagram).

Therefore, in the semiconductor laser 20, the heater 14 is turned on at room temperature and turned off at high temperature, so that the decrease in output at high temperature is suppressed and good high temperature operation characteristics are obtained.

Thus, in the operation of the semiconductor laser 20, since the heater 14 can be turned on when the current injected to the DFB laser is low at room temperature and the heater 14 can be turned off when the current injected to the DFB laser is high at high temperature, power consumption can be equalized from room temperature to high temperature, reducing total power consumption.

According to the semiconductor laser according to the present embodiment, the decrease in output at high temperature can be suppressed, good high-temperature operation characteristics can be obtained, and low power consumption can be realized.

An example of the operation of the semiconductor laser 20 according to the present embodiment will be described below.

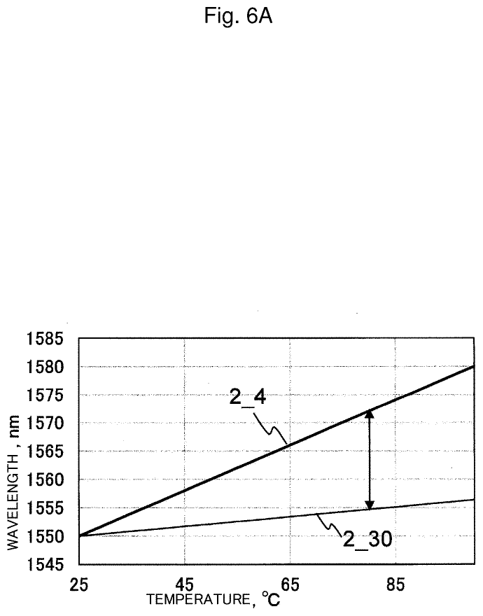

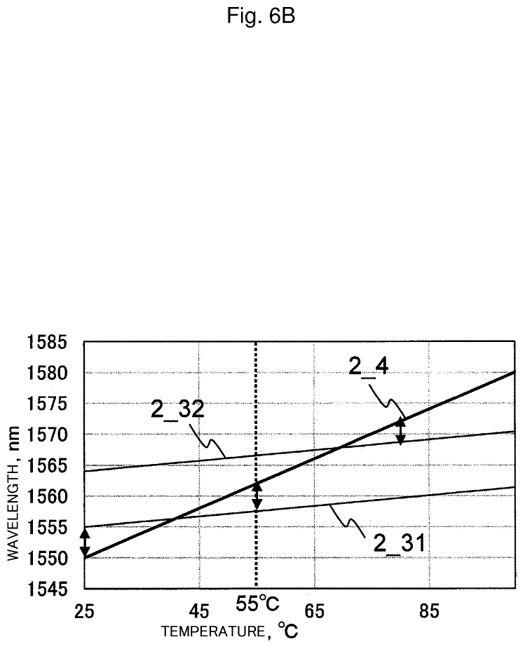

FIGS. 6A and 6B show the results of calculation of temperature dependence between the oscillation peak wavelength and the gain peak wavelength in the DFB laser.

In the calculation, experimental data obtained by the DFB laser is used for the temperature characteristics of a gain and the temperature dependence of an oscillation wavelength, which were set to 0.4 nm/K and 0.085 nm/K, respectively.

As shown in FIG. 6A, when one oscillation wavelength 2_30 in the DFB laser is made to match a gain peak wavelength 2_4 at room temperature and the temperature is increased, both of the oscillation wavelength 2_30 and the gain peak wavelength 2_4 are shifted to the long wavelength side.

Here, the shift amount of the gain peak wavelength 2_4 is larger than the shift amount of the oscillation wavelength 2_30, and the difference therebetween is 18.9 nm at 80° C. (arrow in the diagram). At this time, since the full width at half maximum of the gain spectrum of the normal MOW active layer 113 is approximately 40 nm, it is estimated that the gain is reduced to approximately half.

FIG. 6B shows an example of the relationship between the temperature dependence of two oscillation wavelengths 2_31 and 2_32 in the DFB laser and the temperature dependence of the gain peak wavelength 2_4.

Here, the difference between the two oscillation wavelengths 2_31 and 2_32, that is, the stopband width (wavelength switching width), is set to 9 nm. In this case, by switching the oscillation wavelength at 55° C., the difference between the oscillation wavelengths 2_31, 2_32 and the gain wavelength 2_4 is approximately 5 nm at room temperature (25° C.), 55° C., and 80° C., respectively (arrows in the diagram).

Thus, when the oscillation wavelengths of the two DFB lasers are used, the temperature range covered by the oscillation wavelength of one DFB laser becomes half, and when the DFB laser having a wavelength switching width of 9 nm is used, the deviation between the gain wavelength and the oscillation wavelength can be reduced to 5 nm or less.

Next, the configuration of a diffraction grating for realizing a wavelength switching width of 9 nm in the DFB laser will be described.

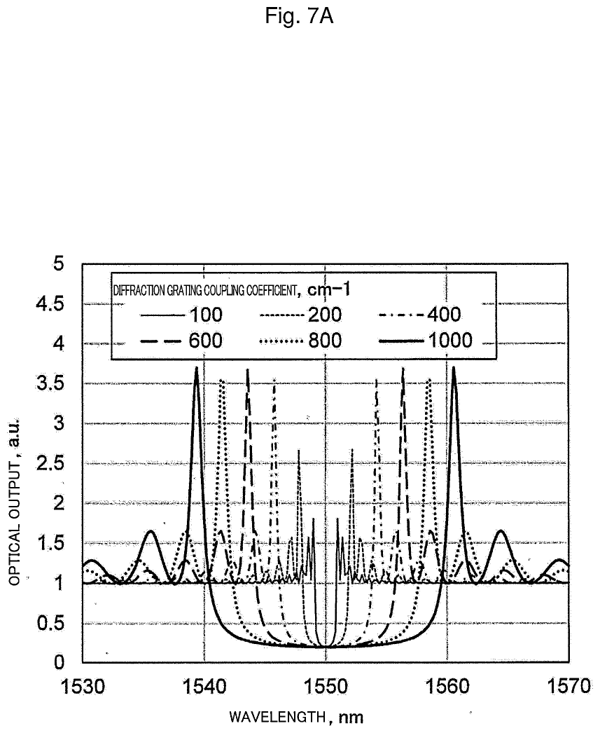

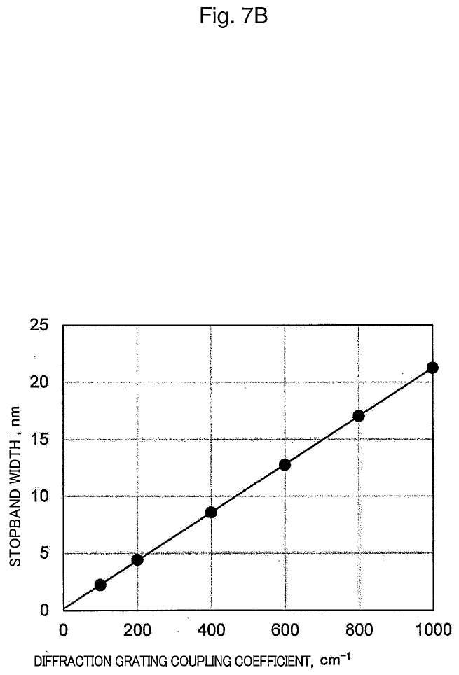

FIG. 7A shows a reflection spectrum obtained when the coupling coefficient of the diffraction grating of the DFB is changed in a 1.55-μm wavelength band. Here, the equivalent refractive index of the active layer region was 2.7 for the 1.55-μm wavelength band and 2.9 for the 1.31-μm wavelength band. The calculation was performed by changing the active layer length L so that the product (κ·L) of the diffraction grating coupling coefficient k and the active layer length L was 5. Two maximum peaks are observed in each spectrum, and the peak interval, that is, the stopband width, increases as the coupling coefficient increases.

FIG. 7B shows the coupling factor dependence of the stopband width of the DFB diffraction grating in a 1.55-μm wavelength band. It can be understood from this that a coupling coefficient of approximately 400 cm⁻¹ is required to obtain a wavelength switching width of 9 nm.

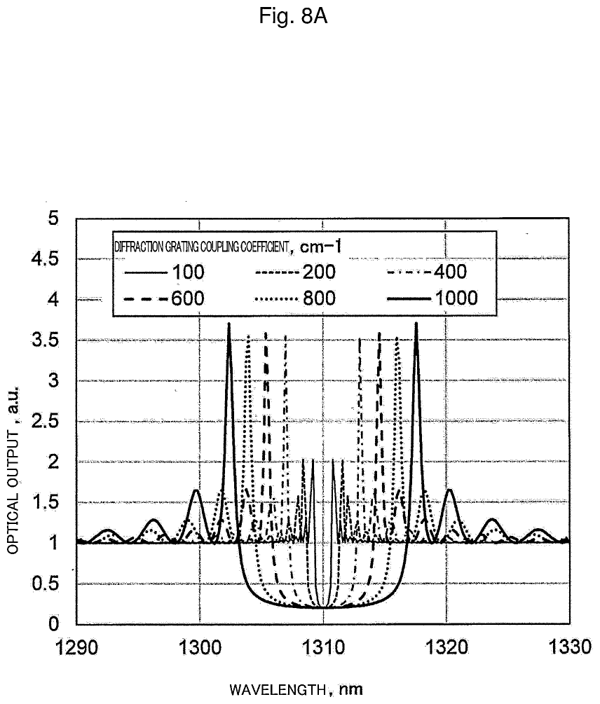

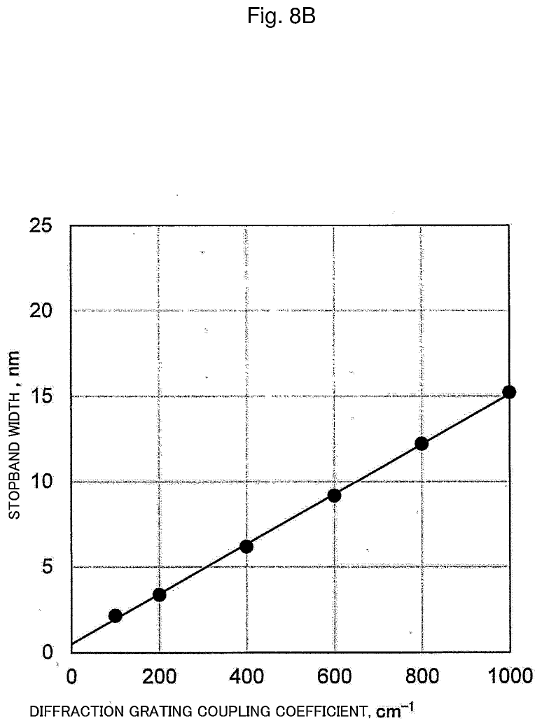

Further, as shown in FIG. 8A, similarly in the 1.31-μm wavelength band, the stopband width increases as the coupling coefficient increases.

It can be understood from FIG. 8B that a coupling coefficient of approximately 600 cm⁻¹ is required to obtain a wavelength switching width of 9 nm in a 1.31-μm wavelength band.

In an ordinary InP-based DFB laser, a diffraction grating is formed between InP and InGaAsP. Therefore, since the coupling coefficient depends on the refractive index difference between InP and InGaAsP, it is difficult to set the coupling coefficient to 100 cm-1 or more and the stopband width to 2 to 3 nm or more.

On the other hand, since the semiconductor laser 20 according to this embodiment is a membrane type laser having a thin film structure surrounded by a medium having a low refractive index such as air, a diffraction grating is formed between InP and the medium having a low refractive index such as SiO₂ or air. Therefore, since the coupling coefficient depends on the refractive index difference between InP and SiO₂, air or the like, the coupling coefficient can be set to approximately 900 cm⁻¹ and the stopband width can be set to approximately 10 to 20 nm.

Therefore, by using the semiconductor laser according to the present embodiment, coupling coefficients of 400 cm-1 and 600 cm⁻¹ can be set in the DFB diffraction grating, and the stopband width of the DFB wavelength can be set to approximately 9 nm. Therefore, the deviation between the gain wavelength and the oscillation wavelength can be reduced to 5 nm or less, and the decrease in output at the time of high temperature can be suppressed.

Although the present embodiment has described an example in which the heater 14 is disposed at a position where the temperatures of the second diffraction grating 221_1 and the third diffraction grating 221_2 can be raised, the heater 14 may be disposed at a position where only the temperature of the second diffraction grating 221_1 can be raised.

Although the present embodiment has described an example in which the two DBR diffraction gratings are arranged in the DBR region, the present invention is not limited thereto. Three or more DBR diffraction gratings may be arranged. Further, a modulation diffraction grating or a sampled diffraction grating may be arranged in the DBR region.

Although the embodiments of the present invention have described an example in which the wavelength of the DBR region is shifted by the heater, the present invention is not limited thereto. An electrode connected to a power source may be arranged in the waveguide layer of the DBR region, and a reverse bias may be applied to extract a carrier, thereby changing the refractive index to shift the wavelength of the DBR region. In this manner, a configuration for changing the refractive index of the DBR region (hereinafter referred to as a “refractive index control unit”) may be provided.

If the refractive index control unit is a heater, the heater is turned on to increase the temperature of the DBR region, thereby increasing the refractive index. Further, the refractive index can be increased by turning on the refractive index control unit and applying a reverse bias to the DBR region to extract a carrier. In this manner, the refractive index of the DBR region can be increased in a state where the refractive index control unit is on, and the wavelength of the DBR region can be shifted to the long wavelength side.

In the embodiments of the present invention, a state in which the emission wavelength of the DFB diffraction grating matches the Bragg wavelength of the DBR diffraction grating refers to, for example, as shown in FIG. 2A, a state in which the emission peak in the emission spectrum of the DFB diffraction grating and a broad peak in the reflection spectrum of the DBR diffraction grating overlap each other. At this time, since only one stopband emission (for example, the short wavelength side) of the DFB diffraction grating is subjected to feedback by the DBR diffraction grating, the light emission from the short wavelength side stopband can be extracted in the DFB diffraction grating.

The embodiments of the present invention have described an example in which the ring resonator and the DBR region are optically coupled to the gain region, but in this case, the waveguides in the ring resonator and the DBR region may be optically coupled to the active layer of the gain region.

The embodiments of the present invention have described an example of a configuration of a semiconductor laser with wavelength bands of 1.55 μm and 1.31 μm, but other wavelength bands may be used. In addition, an example of a configuration using an InP-based compound semiconductor has been described as a layer configuration of a semiconductor laser such as an active layer, a waveguide layer, and p-type and n-type semiconductor layers, but other InP-based compound semiconductors may be used, other semiconductors such as GaAs-based or Si-based semiconductors may be used, and a material capable of constituting a semiconductor laser may be used.

Although the embodiments of the present invention have described examples of structures, dimensions, materials, and the like of each component in the configurations of the semiconductor laser, the present invention is not limited thereto. Any modifications can be made as long as the modifications bring about the functions of a semiconductor laser and achieves the effects.

### INDUSTRIAL APPLICABILITY

The present invention can be applied to light-emitting devices in Internet communication systems, computer systems, and the like.

Reference Signs List

| | |
|---|---|
| 10 | Semiconductor laser |
| 111 | First diffraction grating |
| 112 | First semiconductor layer |
| 113 | Active layer |
| 114 | Second semiconductor layer |
| 115_1 | p-type semiconductor layer |
| 115_2 | n-type semiconductor layer |
| 121 | Second diffraction grating |
| 122 | Waveguide layer |
| 14 | Refractive index control unit |

1. A semiconductor laser, comprising:
a waveguide structure including, in order, a first semiconductor layer, an active layer, and a second semiconductor layer;
a p-type semiconductor layer disposed in contact with one side surface of the active layer;
an n-type semiconductor layer disposed in contact with the other side surface of the active layer;
a waveguide layer optically coupled to the active layer in a waveguide direction;
a first diffraction grating disposed on either one of a lower surface of the first semiconductor layer, an upper surface of the second semiconductor layer, and a side surface of the active layer;
a second diffraction grating disposed on either one of a lower surface and an upper surface of the waveguide layer; and
a refractive index control unit for changing a refractive index of the waveguide layer.

2. The semiconductor laser according to claim 1, wherein the first diffraction grating has two stopband edge emission wavelengths,
when the refractive index control unit is off, the stopband edge emission wavelength on a short wavelength side of the first diffraction grating is selected and oscillated by the second diffraction grating, and
when the refractive index control unit is on, the stopband edge emission wavelength on the long wavelength side of the first diffraction grating is selected and oscillated by the second diffraction grating.

3. The semiconductor laser according to claim 2, further comprising a third diffraction grating optically coupled to the second diffraction grating in the waveguide direction,
wherein a Bragg wavelength of the third diffraction grating is longer than a Bragg wavelength of the second diffraction grating, and
the Bragg wavelength of the second diffraction grating is shorter than the stopband end emission wavelength on the short wavelength side.

4. The semiconductor laser according to claim 3, wherein the first diffraction grating has two stopband edge emission wavelengths,
when the refractive index control unit is on, the stopband edge emission wavelength on the short wavelength side of the first diffraction grating is selected and oscillated by the second diffraction grating, and
when the refractive index control unit is off, the stopband edge emission wavelength on the long wavelength side of the first diffraction grating is selected and oscillated by the third diffraction grating.

5. The semiconductor laser according to claim 1, wherein the waveguide layer includes the second diffraction grating and the refractive index control unit via a predetermined interval from the active layer.

6. The semiconductor laser according to claim 1, wherein the refractive index control unit is a heater.

7. The semiconductor laser according to claim 1, wherein the refractive index control unit is an electrode connected to a power source and arranged in the waveguide layer, the electrode being applied with a bias to change a carrier density of the waveguide layer.

8. The semiconductor laser according to claim 2, wherein the waveguide layer includes the second diffraction grating and the refractive index control unit via a predetermined interval from the active layer.

9. The semiconductor laser according to claim 3, wherein the waveguide layer includes the second diffraction grating and the refractive index control unit via a predetermined interval from the active layer.

10. The semiconductor laser according to claim 4, wherein the waveguide layer includes the second diffraction grating and the refractive index control unit via a predetermined interval from the active layer.

11. The semiconductor laser according to claim 2, wherein the refractive index control unit is a heater.

12. The semiconductor laser according to claim 3, wherein the refractive index control unit is a heater.

13. The semiconductor laser according to claim 4, wherein the refractive index control unit is a heater.

14. The semiconductor laser according to claim 5, wherein the refractive index control unit is a heater.

15. The semiconductor laser according to claim 2, wherein the refractive index control unit is an electrode connected to a power source and arranged in the waveguide layer, the electrode being applied with a bias to change a carrier density of the waveguide layer.

16. The semiconductor laser according to claim 3, wherein the refractive index control unit is an electrode connected to a power source and arranged in the waveguide layer, the electrode being applied with a bias to change a carrier density of the waveguide layer.

17. The semiconductor laser according to claim 4, wherein the refractive index control unit is an electrode connected to a power source and arranged in the waveguide layer, the electrode being applied with a bias to change a carrier density of the waveguide layer.

18. The semiconductor laser according to claim 5, wherein the refractive index control unit is an electrode connected to a power source and arranged in the waveguide layer, the electrode being applied with a bias to change a carrier density of the waveguide layer.
